(19) United States
(12) Patent Application Publication
(10) Pub. No.: US 2026/0153584 A1
(43) Pub. Date: Jun. 4, 2026

(54) NUCLEAR MAGNETIC RESONANCE (NMR) RINGING NOISE MEASUREMENTS IN WELL SYSTEMS

(71) Applicant: Halliburton Energy Services, Inc., Houston, TX (US)

(72) Inventors: Jie Yang, Houston, TX (US); Rebecca Jachmann, Houston, TX (US); Matthew C. Griffing, Houston, TX (US); Boguslaw Wiecek, Houston, TX (US)

(21) Appl. No.: 18/963,905

(22) Filed: Nov. 29, 2024

(51) Int. Cl. G01R 33/565; G01R 33/561; G01V 3/32

(52) U.S. Cl. CPC G01R 33/56545; G01R 33/5615; G01V 3/32

(57) ABSTRACT

Systems, methods, and apparatus, including computer programs encoded on computer-readable media, for obtaining nuclear magnetic resonance (NMR) measurements of a subsurface formation in a well system. One or more NMR pulses are generated downhole using an NMR tool of the well system. It is determining whether an amplitude of an NMR echo signal is less than or equal to a threshold level or the NMR echo signal is not present. Ringing noise associated with the one or more NMR pulses is measured when the amplitude of the NMR echo signal is less than or equal to the threshold level or the NMR echo signal is not present. The ringing noise is cancelled from the NMR measurements, and properties of the subsurface formation are determined from the NMR measurements after cancelling the ringing noise.

### TECHNICAL FIELD

The present invention relates generally to oil and gas systems and services, and more specifically to performing nuclear magnetic resonance (NMR) ringing noise measurements in well systems.

### BACKGROUND

The oil and gas services industry uses various types of well equipment and tools in well systems at well sites. Well systems may use nuclear magnetic resonance (NMR) tools for NMR logging of the subsurface formation of a well for hydrocarbon reservoir evaluation. For example, the NMR logging may indicate the volume (e.g., porosity) and distribution (e.g., permeability) of the rock pore space, the rock composition, the type and quality of the fluids (e.g., water and hydrocarbons), and hydrocarbon producibility. Ringing noise is one of the primary challenges that impacts the accuracy of NMR measurement acquired using NMR tools. Ringing noise also places limitations on NMR measurements, such as placing a minimum limit on the inter-echo spacing time of an NMR echo train. Traditional techniques for removing ringing noise, such as the phase-alternate pulse sequence (PAPS) technique or the phase-alternated-pair (PAP) technique, typically require two or more NMR echo trains. To acquire two or more NMR echo trains, the operator runs multiple experiments to acquire the different sets of NMR measurements for the two or more NMR echo trains, which takes additional time and is costly. Furthermore, the ringing noise and/or the NMR echo amplitudes can change over time, such as when the NMR tool undergoes a lateral motion, and thus the ringing noise measurements obtained from different NMR echo trains can lead to results that may not accurately cancel the ringing noise in the NMR measurements. If additional signal processing steps are performed to account for the effects of the lateral motion, additional complexity is added to the ringing noise cancellation process, which can further increase cost and inefficiencies.

### BRIEF DESCRIPTION OF THE DRAWINGS

FIG. 1 depicts a schematic diagram of an example well system including a nuclear magnetic resonance (NMR) tool, according to some implementations.

FIG. 2A depicts an example signal diagram of an NMR echo train, according to some implementations.

FIG. 2B depicts an example signal diagram of the NMR echo train that shows the decay curve of an NMR echo signal, according to some implementations.

FIG. 3A depicts an example signal diagram of the NMR echo train including the ringing noise, according to some implementations.

FIG. 3B depicts an example signal diagram of the NMR echo train including an echo window with a decayed NMR echo signal for measuring ringing noise, according to some implementations.

FIG. 4 depicts another example signal diagram of the NMR echo train including an echo window with a decayed NMR echo signal for measuring ringing noise, according to some implementations.

FIG. 5 depicts an example signal diagram of a shortened NMR echo train that includes a nullification pulse for measuring ringing noise, according to some implementations.

FIG. 6 depicts an example signal diagram of a nullification pulse and one or more refocusing pulses for measuring ringing noise, according to some implementations.

FIG. 7 depicts an example signal diagram of one or more refocusing pulses for measuring ringing noise, according to some implementations.

FIG. 8 is a flowchart of example operations for performing NMR measurements of a subsurface formation in a well system, according to some implementations.

FIG. 9 depicts an example computer system that can be implemented in surface equipment of a well system for performing NMR measurements of a subsurface formation, according to some implementations.

FIG. 10 shows an example well system that includes an NMR tool in a wireline logging environment, according to some implementations.

FIG. 11 shows an example well system that includes an NMR tool in a drilling environment, according to some implementations.

FIG. 12 is a diagram of an example NMR magnet and antenna(s) configuration, according to some implementations.

### DESCRIPTION

The description that follows includes example systems, methods, techniques, and program flows that describe aspects of the disclosure. However, it is understood that this disclosure may be practiced without these specific details. For instance, this disclosure refers to certain well systems, devices, or tools in illustrative examples. Aspects of this disclosure can be instead applied to other types of well systems, devices, and tools. In other instances, well-known instruction instances, protocols, structures, and techniques have not been shown in detail to avoid confusion.

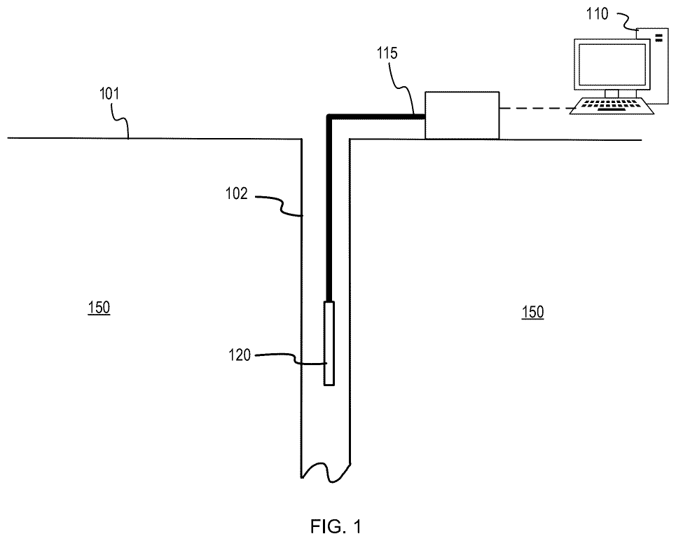

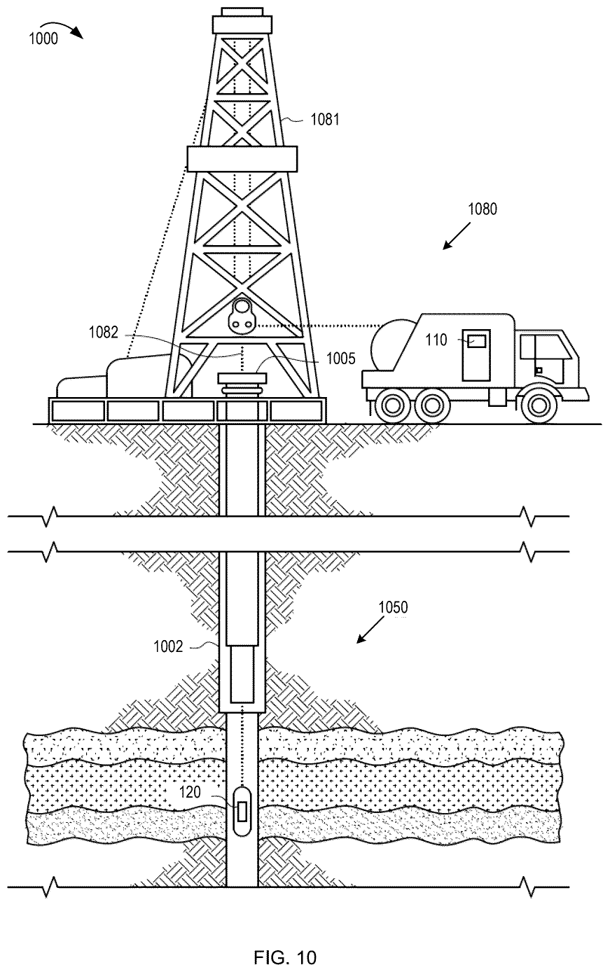

FIG. 1 depicts a schematic diagram of an example well system 100 including a nuclear magnetic resonance (NMR) tool, according to some implementations. In some implementations, the well system 100 may include a wellbore 102, surface equipment and tools, such as the computer system 110, and downhole equipment and tools, such as the NMR tool 120. The well system 100 may also include a cable 115 (e.g., a wireline) or other mechanism (such as a work string or drill string) that can lower the NMR tool 120 downhole into the wellbore 102 (or borehole). FIG. 1 shows a portion of the wellbore 102 and well system 100 for simplicity. It is noted that the well system 100 may include additional equipment, devices, tools and other components at the surface 101 or downhole that are not shown for simplicity. The well system 100 may use the NMR tool 120 for NMR logging of the subsurface formation 150 of the wellbore 102 for hydrocarbon reservoir evaluation. For example, the NMR logging may indicate various properties of the subsurface formation 150, such as the volume (e.g., porosity) and distribution (e.g., permeability) of the rock pore space, the rock composition, the type and quality of the fluids (e.g., water and hydrocarbons), and hydrocarbon producibility, among others. Therefore, the measurements and other data obtained from the NMR logging can be used for well site planning, well drilling, hydrocarbon recovery operations, and other well operations. Non-limiting examples of the well system 100 and the NMR tool 120 are further described in FIGS. 10-12.

Ringing noise is one of the primary challenges that impacts the accuracy of NMR measurement acquired or obtained using NMR tools. Ringing noise also places limitations on NMR measurements, such as placing a minimum limit on the inter-echo spacing time of an NMR echo train. Traditional techniques for removing ringing noise, such as the phase-alternate pulse sequence (PAPS) technique or the phase-alternated-pair (PAP) technique, typically require two or more NMR echo trains. When a second NMR echo train is required by the traditional techniques to perform the ringing noise cancellation process, a significant polarization wait time is needed to allow the permanent magnet to repolarize before the second NMR echo train can be obtained. Multiple NMR experiments are typically run to acquire the different sets of NMR measurements for the two or more NMR echo trains with longer wait times, which takes additional time and reduces the resolution of data delivered. Also, from one NMR echo train to another NMR echo train, the NMR tool 120 typically experiences a different lateral motion. The identification and thus the ability to remove the ringing effect can be difficult when the tool undergoes a lateral motion, because the echo amplitudes and/or the ringing noise can vary with the varying lateral motion. Therefore, the cancellation results may not accurately cancel the ringing noise when using two or more NMR echo trains are used. If additional signal processing steps are performed to account for the effects of the lateral motion, additional complexity is added to the ringing noise cancellation process, which can further increase cost and inefficiencies.

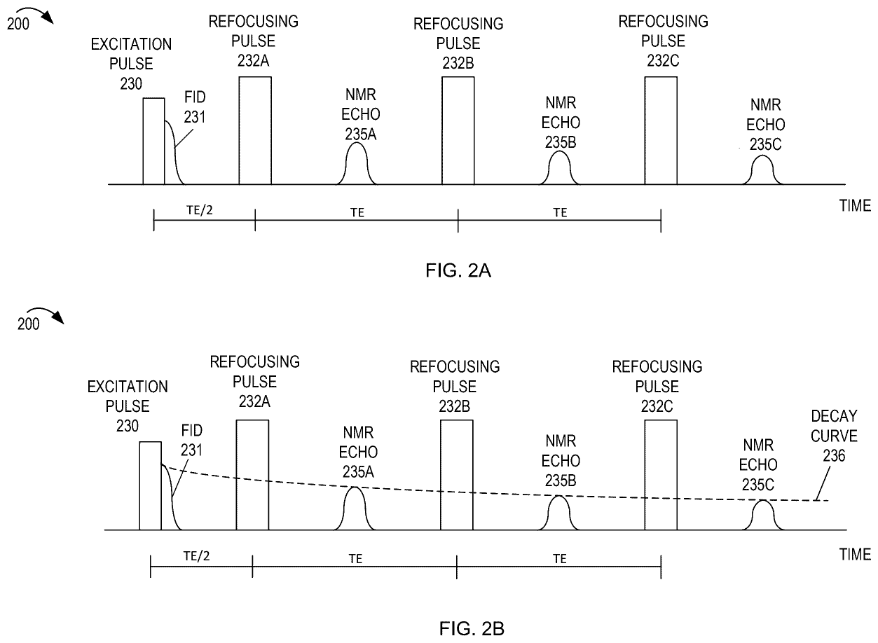

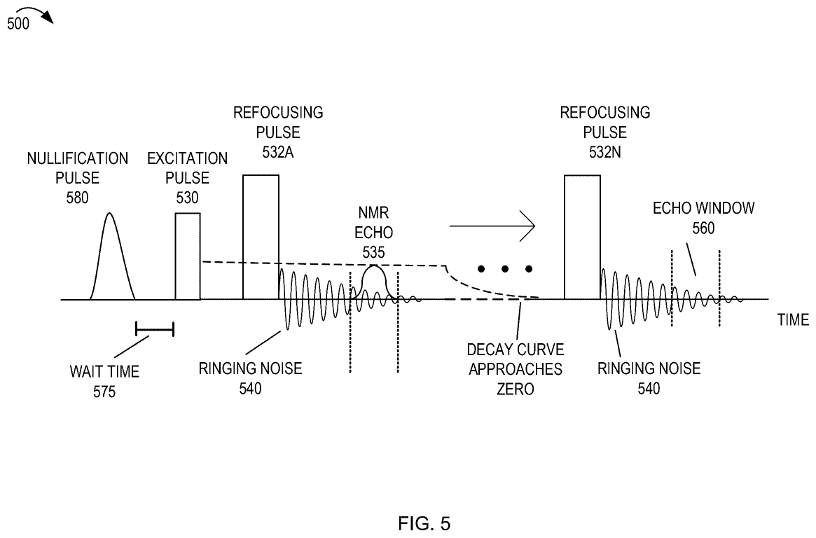

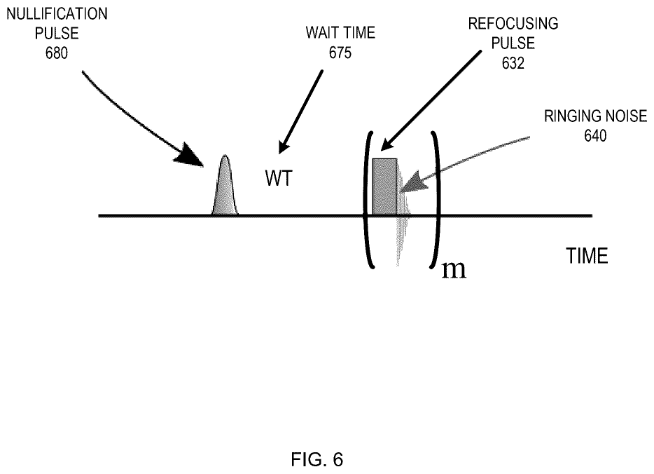

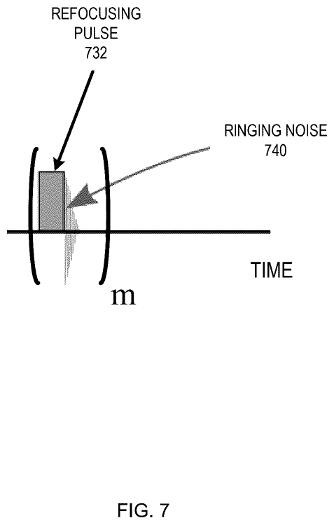

According to some implementations of the present disclosure, the well system 100, using measurements obtained from the NMR tool 120, may measure the ringing noise from a single NMR echo train, as further described below in FIGS. 2-5. In some implementations, the well system 100 may measure the ringing noise prior to the NMR echo train, as further described below in FIGS. 6-7. In some implementations, by using a long enough NMR echo train to effectively reduce the echo amplitudes to a negligible level, the ringing noise can be measured directly toward the end of the NMR echo train without the need for a second NMR echo train or additional NMR echo trains. When the echo amplitudes drop below a threshold level due to a natural decay curve, those echoes can be used to identify and measure the ringing noise using a single NMR echo train, as further described below in FIGS. 2-4. Using a single echo train to measure the ringing noise or measuring the ringing noise prior to the echo train reduces the time to measure the ringing noise and thus can make the measurement process more efficient and less costly. Furthermore, the lateral motion of the NMR tool 120 may not affect the NMR measurements when a single NMR echo train is used or when the NMR measurements are performed prior to the NMR echo train, and thus the cancellation results may accurately cancel the ringing noise and may also improve the vertical resolution associated with the NMR tool 120. In some implementations, the well system 100 may measure the ringing noise from a single, shortened NMR echo train by using a nullification pulse, as further described below in FIG. 5. In some implementations, the well system 100 may measure the ringing noise using a nullification pulse and one or more refocusing pulses (and without generating an NMR echo signal), as further described below in FIG. 6. In some implementations, the well system 100 may measure the ringing noise using one or more refocusing pulses (and without generating an NMR echo signal), as further described below in FIG. 7. The different ringing noise measurement techniques isolate the ringing noise in order to measure the ringing noise. In some implementations, after measuring the ringing noise, the ringing noise can be subtracted or removed or cancelled from the NMR echo train (e.g., from the NMR echo signal of the NMR echo train). After removing or cancelling the ringing noise, the NMR measurements (e.g., the NMR echo signals) can be used by various tools and products and services for NMR logging and well-related tasks, as described above.

FIG. 2A depicts an example signal diagram of an NMR echo train 200, according to some implementations. In some implementations, an NMR tool (such as the NMR tool 120 of FIG. 1) can use a pulse sequence (e.g., such as a Carr-Purcell-Meiboom-Gill (CPMG) pulse sequence or train), where the transmitter of the NMR tool applies an excitation pulse 230 (which may also be referred to as a 90° pulse, although the degree amount may vary in some implementations) to the antenna to tip the nuclear spin that was polarized or aligned by the permanent magnet. After the excitation pulse 230, the NMR tool may generate a number of refocusing pulses 232A-232C (which may also be referred to as 180° pulses, although the degree amount may vary in some implementations). The refocusing pulses 232A-232C (and any additional refocusing pulses not shown) may generally and collectively be referred to as the refocusing pulses 232. As shown in FIG. 2A, after the excitation pulse 230, a free induction decay (FID) signal 231 is generated, which can be detected as the spins start to de-phase. The refocusing pulses 232 flip the fast and slow spins allowing them to start to recover coherence. As the spins become more coherent, NMR echo signals 235A-235C can be measured at a receiver antenna of the NMR tool. The NMR echo signals 235A-235C (and any additional NMR echo signals not shown) may generally and collectively be referred to as the NMR echo signals 235. In some implementations, the refocusing pulses 232 are repeated at a time TE, which may also be referred to as an echo time. The excitation pulse 230, the FID 231, the refocusing pulses 232, and the NMR echo signals 235 may be referred to as the NMR echo train 200. It is noted that the NMR echo train 200 may include additional refocusing pulses 232 and NMR echo signals 235 that are not shown for simplicity, as further described below.

FIG. 2B depicts an example signal diagram of the NMR echo train 200 that shows the decay curve 236 of the NMR echo signals, according to some implementations. As described in FIG. 2A, the NMR echo train 200 may include the excitation pulse 230, the FID 231, the refocusing pulses 232 (e.g., refocusing pulses 232A-232C), and the NMR echo signals 235 (e.g., NMR echo signals 235A-235C). The refocusing pulses 232 can be repeated at a time TE, which may also be referred to as an echo time. In some implementations, as shown in FIG. 2B, the NMR echo signals 235 have decreasing amplitudes due to irreversible dephasing caused by dipolar interactions and diffusion processes, since the spins cannot be completely refocused. This results in a decay curve 236 for the amplitude of the NMR echo signals 235, as shown by the dashed line. Eventually, if the NMR echo train 200 is long enough, the echo amplitudes will typically become negligible or effectively 0 toward at or toward the end of the NMR echo train 200, as further described below.

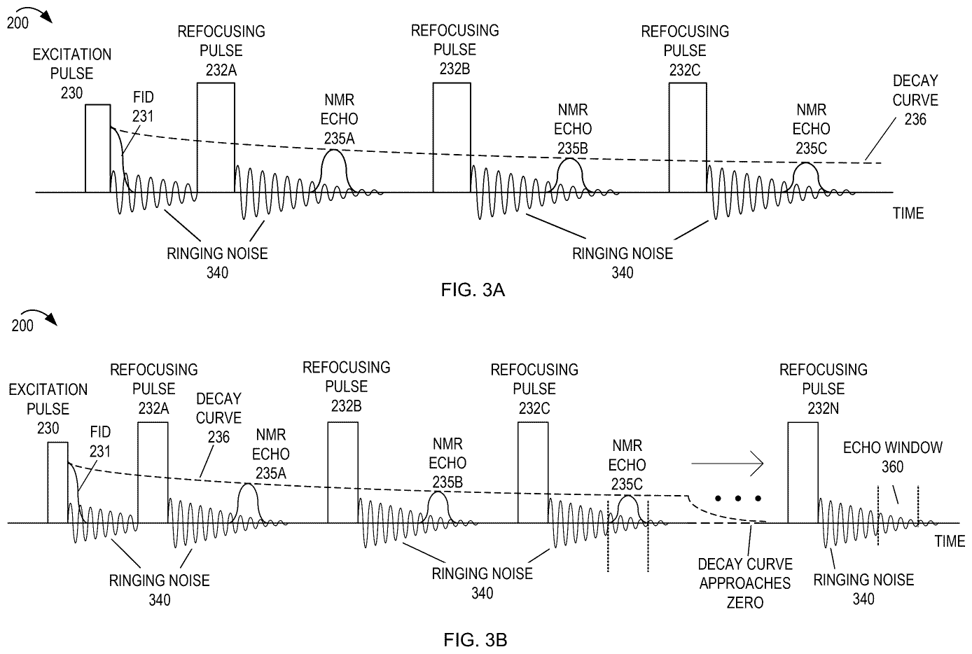

FIG. 3A depicts an example signal diagram of the NMR echo train 200 including the ringing noise 340, according to some implementations. As described in FIGS. 2A-2B, the NMR echo train 200 may include the excitation pulse 230, the FID 231, the refocusing pulses 232 (e.g., refocusing pulses 232A-232C), and the NMR echo signals 235 (e.g., NMR echo signals 235A-235C). In some implementations, during NMR logging, when the transmitter of the NMR tool (e such as the NMR tool 120 of FIG. 1) applies a pulse to the antenna, an electromechanical effect called “ringing” occurs. The ringing effect is due to the torque associated with the variable force produced by the interaction of the alternating current flowing through the antenna and the permanent magnet field. This produces vibration at the excitation frequency and induces an electrical signal in the antenna which is referred to as ringing noise (such as the ringing noise 340 shown in FIG. 3A). Although the ringing noise 340 decays quite rapidly, the amplitude of the ringing noise 340 can be relatively large and still be present during the NMR echo signal detection period, which can contaminate or completely drown out the NMR echo signals 235, as shown in FIG. 3A. In some implementations, a well system (such as the well system 100 of FIG. 1) may use the properties of the decay curve 236 of the NMR echo signals 235 to measure the ringing noise 340 when the amplitude of the NMR echo signals 235 is at or below a threshold level, such as when the amplitude of the NMR echo signals 235 decays to a level that is at or below the noise level (or noise floor level) or when the amplitude becomes negligible as it approaches zero, as further described below in FIG. 3B.

FIG. 3B depicts an example signal diagram of the NMR echo train 200 including an echo window with a decayed NMR echo signal for measuring ringing noise 340, according to some implementations. In some implementations, an NMR tool of a well system (such as the NMR tool 120 of the well system 100 of FIG. 1) may generate one or more NMR pulses to perform or acquire NMR measurements downhole for the subsurface formation. As shown in FIG. 3B, the NMR tool may generate an excitation pulse 230 and the refocusing pulses 232 (e.g., the refocusing pulses 232A-232N) of the NMR echo train 200, and may detect the NMR echo signals 235 (e.g., the NMR echo signals 235A-235C) of the NMR echo train 200. The NMR echo train 200 may include additional NMR echo signals 235 with decreasing amplitude that follow the decay curve 236, which are not shown for simplicity. In some implementations, the NMR tool may be configured to generate relatively long NMR echo trains, where the echo amplitude decays to effectively 0 (negligible) (e.g., such as echo window 360) and the ringing noise 340 can be measured and analyzed directly towards the end of the NMR echo train 200, without having to generate two or more echo trains. This particular pulse sequence may be referred to as a long NMR echo train or a T2 pulse sequence. In some implementations, as the amplitude of the NMR echo signals 235 decay, the well system may determine whether the amplitude of each NMR echo signal 235 is less than or equal to a threshold level. In one example, the threshold level may be a noise level. In another example, the threshold level may be a signal level when the amplitude of the NMR echo signal 235 is less than the amplitude of the ringing noise 340. In another example, the threshold level may be a signal level representing the NMR echo signal 235 decaying toward a zero amplitude or a signal level approximately equal to a zero amplitude (or a negligible amplitude). In some implementations, the well system may measure the ringing noise associated with one or more of the refocusing pulses 232 of the NMR echo train 200 (i.e., a single NMR echo train) when the amplitude of the NMR echo signals 235 are less than or equal to the threshold level, as shown in echo window 360. Once the NMR echo signals 235 have decayed to a signal level at or below the threshold level, the ringing noise 340 can be isolated, measured and investigated for one or more of the refocusing pulses 232 of a single NMR echo train, such as the NMR echo train 200.

In some implementations, when the NMR echo signals 235 have an amplitude less than or equal to the threshold level, the well system may measure the ringing noise 340 associated with one of the refocusing pulses 232 of the NMR echo train 200. For example, the well system may measure the ringing noise 340 associated with the refocusing pulse 232N. In some implementations, when the NMR echo signals 235 have an amplitude less than or equal to the threshold level, the well system may measure the ringing noise 340 associated with multiple of the refocusing pulses 232 of the NMR echo train 200, and may average the multiple measurements of the ringing noise 340.

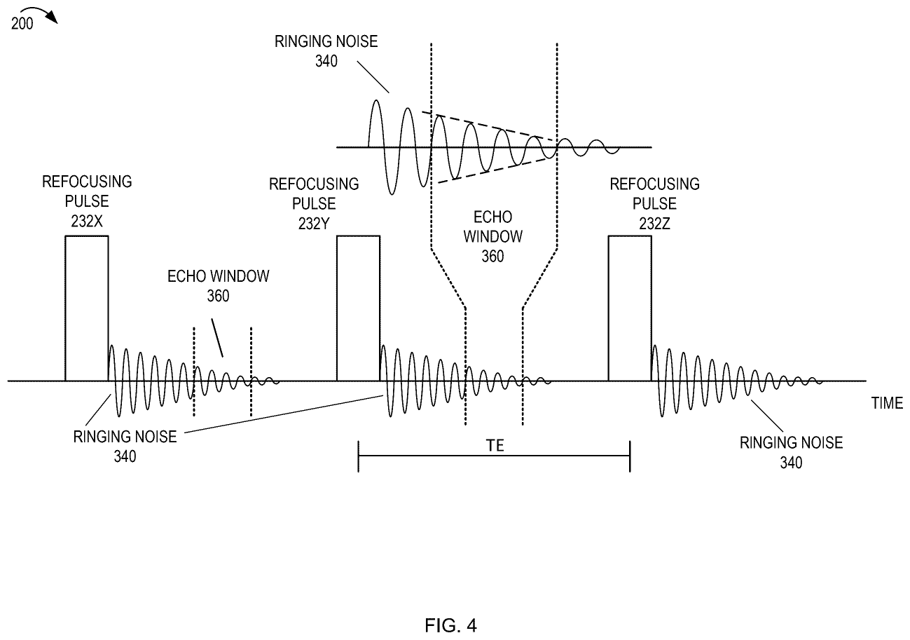

FIG. 4 depicts another example signal diagram of the NMR echo train 200 including an echo window with a decayed NMR echo signal for measuring ringing noise 340, according to some implementations. FIG. 4 shows the NMR echo train 200 after the NMR echo signals have decayed at approximately zero. As described in FIG. 3B, in some implementations, the well system may measure the ringing noise associated with one or more of the refocusing pulses 232 of the NMR echo train 200 (i.e., a single NMR echo train) when the amplitude of the NMR echo signals are less than or equal to the threshold level (e.g., the amplitudes of the NMR echo signals are approaching zero), as shown in echo window 360. In some implementations, when the NMR echo signals 235 have an amplitude less than or equal to the threshold level, the well system may measure the ringing noise 340 associated with one of the refocusing pulses 232 of the NMR echo train 200, such as the refocusing pulse 232X. In some implementations, when the NMR echo signals 235 have an amplitude less than or equal to the threshold level, the well system may measure the ringing noise 340 associated with multiple of the refocusing pulses 232 of the NMR echo train 200, such as the ringing noise 340 associated with refocusing pulse 232X, refocusing pulse 232Y, and refocusing pulse 232Z. After measuring the ringing noise 340 associated with multiple refocusing pulses 232, the well system average the multiple measurements of the ringing noise 340. The signal to noise ratio (SNR) of the signal may be increased by averaging multiple measurements of the ringing noise 340. After obtaining the measurement of the ringing noise 340, the well system may cancel or subtract the ringing noise 340 from the measurements of the NMR echo signals 235 to correct the NMR echo train measurements and accurately measure the NMR echo signals 235. Furthermore, the more accurate ringing noise measurements may reduce the inter-echo spacing time (TE) of the NMR echo trains.

In some implementations, the well system may take multiple measurements of the ringing noise for a first NMR echo train to obtain an average ringing noise measurement for the first NMR echo train. Additional, in some implementations, the well system may keep a running average of ringing noise measurements by taking multiple measurements of ringing noise in a second NMR echo train, and averaging the ringing noise measurements from the second NMR echo train with the ringing noise measurements from the first NMR echo train. In some implementations, the running average of the ringing noise measurements can be taken across any number of NMR echo trains (e.g., two or more echo trains).

FIG. 5 depicts an example signal diagram of a shortened NMR echo train 500 that includes a nullification pulse for measuring ringing noise 540, according to some implementations. In some implementations, the shortened NMR echo train 500 may include a nullification pulse 580, an excitation pulse 530, refocusing pulses 532A-N, and NMR echo signal 535A. Although not shown for simplicity, the NMR echo train 500 also includes additional NMR echo signals, e.g., NMR echo signals 535A-N, that follow the decay curve. As shown in FIG. 5, the first pulse in the sequence may be a nullification pulse (which may also be referred to as a saturation pulse) that either nullifies or inverts the polarization of the spins. The spins are then allowed to polarize during the current wait time 575. This results in a varying wait time 575 for polarization in addition to the direct measurements using the refocusing pulses 532. After the nullification pulse 580, the excitation pulse 530 is generated, followed by a number of refocusing pulses 532, similar to FIG. 3B, but with a shortened NMR echo train 500. For a short wait time 575, after the nullification, the polarization level could be rather low. This may mean any polarization which is accumulated during the wait time 575 (which may be represented as WT) should not last any longer than 5*WT. In some implementations, the echo signals 535 may decay toward zero (or approximately zero) after 5*WT, and thus the ringing noise 540 may be measured at any a sequence which has any echoes being acquired past 5*WT. Thus, in the case of a short wait time, such as wait time 575, where polarization is not achieved, the number of NMR echo signals 535 needed before the signal reduces or decays to effectively zero is decreased (compared to NMR echo trains without the nullification pulse 580, such as the NMR echo train 200 shown in FIG. 3B). This particular pulse sequence may be referred to as a shortened NMR echo train or a T1 pulse sequence.

Similar to FIG. 3B, in some implementations, as the amplitude of the NMR echo signals 535 of the shortened NMR echo train 500 decay, the well system may determine whether the amplitude of each NMR echo signal 535 is less than or equal to a threshold level. In one example, the threshold level may be a noise level. In another example, the threshold level may be a signal level when the amplitude of the NMR echo signal 535 is less than the amplitude of the ringing noise 540. In another example, the threshold level may be a signal level representing the NMR echo signal 535 decaying toward a zero amplitude or a signal level approximately equal to a zero amplitude (or a negligible amplitude). In some implementations, when the NMR echo signals 535 have an amplitude less than or equal to the threshold level, the well system may measure the ringing noise 540 associated with one of the refocusing pulses 532 of the NMR echo train 500. For example, the well system may measure the ringing noise 540 associated with the refocusing pulse 532N since the echo window 560 shows a decayed echo amplitude. In some implementations, when the NMR echo signals 535 have an amplitude less than or equal to the threshold level, the well system may measure the ringing noise 540 associated with multiple of the refocusing pulses 532 of the NMR echo train 500, and may average the multiple measurements of the ringing noise 540.

FIG. 6 depicts an example signal diagram of a nullification pulse 680 and one or more refocusing pulses 632 for measuring ringing noise 640, according to some implementations. In some implementations, an NMR tool (e.g., such as the NMR tool 120 of FIG. 1) may generate the nullification pulse 680 without generating an excitation pulse and an NMR echo train, or may wait to generate the excitation pulse and the NMR echo train until a later time. Besides measuring ringing noise, this sequence of pulses may be used for various purposes, such as testing refocusing pulses. In some implementations, the nullification pulse 680 is generated, and after a short wait time (WT) 675, one or more refocusing pulses 632 can be generated. For example, m sequences of refocusing pulses 632 can be generated. In this implementation, as shown in FIG. 6, an NMR echo signal will not be present in each sequence of the refocusing pulses 632, and therefore, an NMR echo signal will not be detected. However, in some implementations, after taking one or more measurements of the ringing noise 640 with only the nullification pulse 680 and the one or more refocusing pulses 632, the NMR tool may generate an excitation pulse and an NMR echo train to take additional measurements of the ringing noise 640, as further described below. The well system may measure the ringing noise 640 after one or more of the refocusing pulses 632. In some implementations, the well system may measure the ringing noise 640 associated with one of the refocusing pulses 632. In some implementations, the well system may measure the ringing noise 640 associated with multiple of the refocusing pulses 632, and may average the multiple measurements of the ringing noise 640.

In some implementations, the well system may take a first set of measurements of the ringing noise 640 associated with one or more the refocusing pulses 632. The NMR tool may also generate an excitation pulse and an NMR echo train (e.g., similar to the NMR echo trains of either FIG. 3B or FIG. 4) with multiple sequences of additional refocusing pulses and NMR echo signals. The well system may wait until the amplitude of the NMR echo signals decay to a signal level that is at or below a threshold level (e.g., an amplitude at or below a noise level or a level at approximately zero, as described above in FIG. 3B and FIG. 4). The well system may then take a second set of measurements of the ringing noise 640 during one or more of the sequences having the decayed NMR echo signal. Furthermore, the well system may take the average of the first set of measurements of the ringing noise 640 (e.g., based on the nullification pulse 680 and the refocusing pulses 632) and the second set of measurements of the ringing noise 640 (e.g., based on the NMR echo train) to determine an average result for the ringing noise 640.

FIG. 7 depicts an example signal diagram of one or more refocusing pulses 732 for measuring ringing noise 740, according to some implementations. In some implementations, an NMR tool (e.g., such as the NMR tool 120 of FIG. 1) may generate the one or more refocusing pulses 732 without generating an excitation pulse and an NMR echo train, or may wait to generate the excitation pulse and the NMR echo train until a later time. Besides measuring ringing noise, this sequence of pulses may be used for various purposes, such as configuration of the magnet and antenna of the NMR tool. In some implementations, as shown in FIG. 7, the one or more refocusing pulses 732 are generated and an NMR echo signal will not be present in each sequence of the refocusing pulses 732 (therefore, an NMR echo signal will not be detected). For example, m sequences of refocusing pulses 732 can be generated. However, in some implementations, after taking one or more measurements of the ringing noise 740 with only the one or more refocusing pulses 732, the NMR tool may generate an excitation pulse and an NMR echo train to take additional measurements of the ringing noise 740, as further described below. The well system may measure the ringing noise 740 after one or more of the refocusing pulses 732. In some implementations, the well system may measure the ringing noise 740 associated with one of the refocusing pulses 732. In some implementations, the well system may measure the ringing noise 740 associated with multiple of the refocusing pulses 732, and may average the multiple measurements of the ringing noise 740.

In some implementations, the well system may take a first set of measurements of the ringing noise 740 associated with one or more the refocusing pulses 732. The NMR tool may also generate an excitation pulse and an NMR echo train (e.g., similar to the NMR echo trains of either FIG. 3B or FIG. 4) with multiple sequences of additional refocusing pulses and NMR echo signals. The well system may wait until the amplitude of the NMR echo signals decay to a signal level that is at or below a threshold level (e.g., an amplitude at or below a noise level or a level at approximately zero, as described above in FIG. 3B and FIG. 4). The well system may then take a second set of measurements of the ringing noise 740 during one or more of the sequences having the decayed NMR echo signal. The well system may then take the average of the first set of measurements of the ringing noise 740 (e.g., based on the refocusing pulses 732) and the second set of measurements of the ringing noise 740 (e.g., based on the NMR echo train) to determine an average result for the ringing noise 740.

As described above, after obtaining the ringing noise measurements, the ringing noise may be cancelled from the NMR measurements. The well system may use the NMR measurements for NMR logging of the subsurface formation of the wellbore for hydrocarbon reservoir evaluation. For example, the NMR logging may indicate various properties of the subsurface formation, such as the volume (e.g., porosity) and distribution (e.g., permeability) of the rock pore space, the rock composition, the type and quality of the fluids (e.g., water and hydrocarbons), and hydrocarbon producibility, among others. Therefore, the NMR measurements and other data obtained from the NMR logging can be used for well site planning, hydrocarbon recovery operations, and other well operations. In some implementations, well operations associated with the subsurface formation (e.g., such as drilling the well or hydrocarbon recovery) can be determined or modified based on the properties of the subsurface formation derived from the NMR measurements.

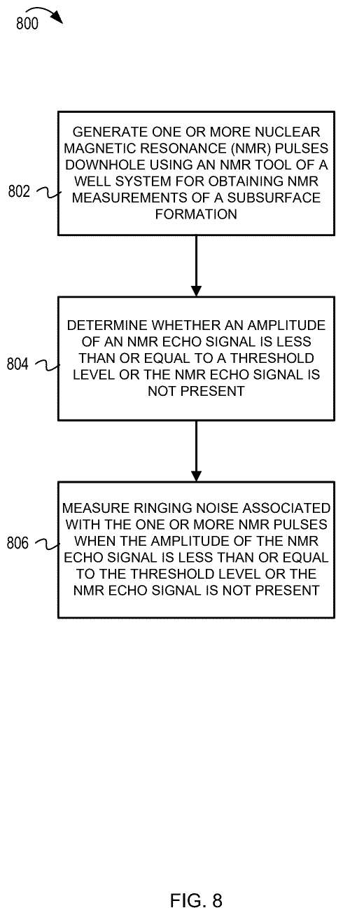

FIG. 8 is a flowchart 800 of example operations for performing NMR measurements of a subsurface formation in a well system, according to some implementations. In some implementations, one or more NMR pulses are generated downhole using an NMR tool of the well system (block 802). In some implementations, it is determined whether an amplitude of an NMR echo signal is less than or equal to a threshold level or the NMR echo signal is not present (block 804). In some implementations, ringing noise associated with the one or more NMR pulses is measured when the amplitude of the NMR echo signal is less than or equal to the threshold level or the NMR echo signal is not present (block 806).

In some implementations, the one or more NMR pulses include an excitation pulse and a plurality of refocusing pulses of an NMR echo train, or the one or more NMR pulses include a nullification pulse, an excitation pulse and a plurality of refocusing pulses of the NMR echo train. The NMR echo signal of the NMR echo train is detected. It is determined when the amplitude of the NMR echo signal is less than or equal to the threshold level. The ringing noise associated with the NMR echo train is measured when the amplitude of the NMR echo signal is less than or equal to the threshold level. In some implementations, the threshold level is a noise level, the threshold level is a signal level when the amplitude of the NMR echo signal is less than an amplitude of the ringing noise, or the threshold level is a signal level representing the NMR echo signal decaying towards a zero amplitude according to a decay curve. In some implementations, the NMR echo train having the nullification pulse results in a shortened NMR echo train by reducing a decay time of the decay curve associated with the NMR echo signal.

In some implementations, the one or more NMR pulses include a plurality of refocusing pulses, or a nullification pulse and a plurality of refocusing pulses. It is determined that the NMR echo signal is not present. The ringing noise associated with one or more of the plurality of refocusing pulses is measured in response to determining the NMR echo signal is not present. In some implementations, the ringing noise is cancelled from the NMR measurements, and properties of the subsurface formation are determined from the NMR measurements after cancelling the ringing noise. In some implementations, a plurality of measurements of the ringing noise are performed, and the plurality of measurements are averaged to obtain an average ringing noise measurement.

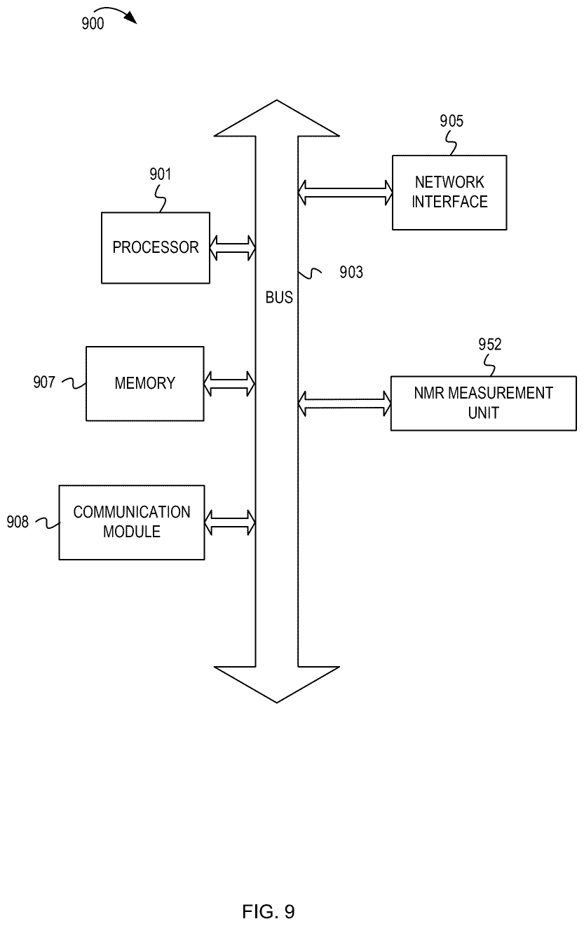

FIG. 9 depicts an example computer system of a well system for performing NMR measurements of a subsurface formation, according to some implementations. In some implementations, the computer system 900 may be an example of a computer system that may be used during the operation of the well system, such as the computer system 110 shown in FIGS. 1, 10 and 11. For example, the computer system 900 may be a standalone computer system (such as a workstation, laptop, or desktop) or may be integrated into other surface equipment of the well system. In some implementations, the computer system 900 may be implemented in downhole components of the well system (e.g., within the NMR tool and/or work string) or the computing functions of the computer system 900 may be distributed across both downhole components (e.g., NMR tool and/or work string) and surface equipment (e.g., workstation or other computer subsystem). The computer system 900 may include one or more processors 901 (possibly including multiple cores, multiple nodes, and/or implementing multi-threading, etc.). The computer system 900 may include memory 907. The memory 907 may be system memory or any type or implementation of machine or computer readable media having instructions that are executable by the one or more processors 901 to implement the operations described in FIGS. 1-8 and 10-12. The memory 907 may be system memory or any type or implementation of machine or computer readable and writable media having the ability to receive, process and/or store measurement data from well devices and tools (including those described in FIGS. 1-8 and 10-12). The computer system 900 also may include a bus 903 and a network interface 905. The computer system 900 also may include a communications module 908 that may control wired and wireless communications, such as communicating with downhole devices or tools and communicating with other surface equipment. The computer system 900 also may include at least an NMR measurement unit 952, among other processing units or modules that are used during the operation of the well system and the well tools described herein (not shown for simplicity). For example, the NMR measurement unit 952 may control above ground and downhole equipment and tools to obtain measurement data, such as controlling an NMR tool that can take NMR measurements downhole of a subsurface formation for NMR logging, as described in FIGS. 1-8 and 10-12. The NMR measurement unit 952 may also cause the NMR tool to generate NMR pulses and may receive, process and analyze NMR measurements. The NMR measurement unit 952 may also measure ringing noise using the techniques described above in FIGS. 1-8 and may cancel or remove the ringing noise from the NMR measurements. In some implementations, the NMR measurement unit 952 (in conjunction with other control and processing units of the computer system 900) may utilize the NMR measurement data (e.g., NMR echo measurements) for determining properties of the subsurface formation and performing well operations based on the properties, as described above. In some implementations, the NMR measurement unit 952 may include a learning machine to perform the operations described above with reference to FIGS. 1-8 for measuring ringing noise, cancelling ringing noise from NMR measurements, and utilizing the NMR measurements. The functionality described herein may be implemented with an application-specific integrated circuit, in logic implemented in the processor(s) 901, in a co-processor on a peripheral device or card, etc. Further, implementations may include fewer or additional components not illustrated in FIG. 9. The processor(s) 901 and the network interface 905 may be coupled to the bus 903. Although illustrated as being coupled to the bus 903, the memory 907 may be coupled to the processor(s) 901.

NMR logging is possible because when an assembly of magnetic moments, such as those of hydrogen nuclei, are exposed to a static magnetic field they tend to align along the direction of the magnetic field, resulting in bulk magnetization. The rate at which equilibrium is established in such bulk magnetization upon provision of a static magnetic field is characterized by the parameter T1, referred to as the spin-lattice relaxation time. Another related NMR logging parameter is T2, referred to as the spin-spin relaxation time constant (also referred to as the transverse relaxation time), which is an expression of the relaxation due to nuclear spins dephasing. NMR logging has two main experiments in oil field downhole usage. The first experiment is to assess T1 buildup of magnetization, and the second experiment is to observe the decay of magnetization once it has been excited, in which the decay has a time constant of T2.

Measurement of T1 is indirect and is done by varying the polarization times after magnetization has, through some means, been nullified or inverted. For downhole observation, a NMR measurement technique, designed by Carr, Purcell, Meiboom, and Gill and, hence, referred to as CPMG, is used. It is considered a T2 measurement. As described previously, CPMG has an excitation pulse followed by several refocusing pulses to counter the magnetic gradients in downhole NMR systems. A T1 sequence is typically performed as: Nullification Pulse-WaitTime-Excitation Pulse-Refocusing pulses. In some cases, the T1 sequence has several different wait times. The number of refocusing pulses may be as few as 3 and as many as associated electronics are configured to handle (e.g., acquire and/or process).

The spin axes of the hydrogen nuclei in the earth formation are, in the aggregate, caused to be aligned with the magnetic field induced in the earth formation by a magnet. The NMR tool (e.g., such as the NMR tool 120 in FIGS. 1 and 10-12) also includes an antenna positioned near the magnet and shaped so that a pulse of RF power conducted through the antenna induces a magnetic field in the earth formation orthogonal to the field induced by the magnet. A receiving antenna (which may be the same antenna as the one that generates the initial RF pulse) is electrically connected to a receiver, which detects and measures voltages induced in the receiving antenna by precessional motion of the spin axes of the nuclei.

An NMR measurement involves a plurality of pulses grouped into pulse sequences, most frequently of a type known as CMPG pulsed spin echo sequences. Each CPMG sequence consists of a 90-degree (i.e., π/2) pulse, which may be an excitation pulse, followed by several refocusing pulses, which may be 180-degree (i.e., π) rotation pulses. The 90-degree pulse rotates the proton spins into the transverse plane and the refocusing pulses generate a sequence of spin echoes by refocusing the transverse magnetization after each spin echo.

NMR well logging data are sensitive to motion of the NMR tool. In an example in which the NMR tool is used in a logging while drilling (LWD) or a measurement while drilling (MWD) context, a lateral motion (e.g., vibration) and rotational movement of drilling operations may cause distortion of the NMR well logging data and, in some cases, an inability to acquire a spin echo signal representing transversal NMR relaxation (i.e., T2 relaxation).

While rotational sensitivity may be reduced by designing the NMR tool to be essentially axially symmetrical, the longitudinal and lateral displacement due to NMR tool motion (e.g., vibration), such as while drilling, remains problematic for NMR data acquisition in a LWD or MWD context.

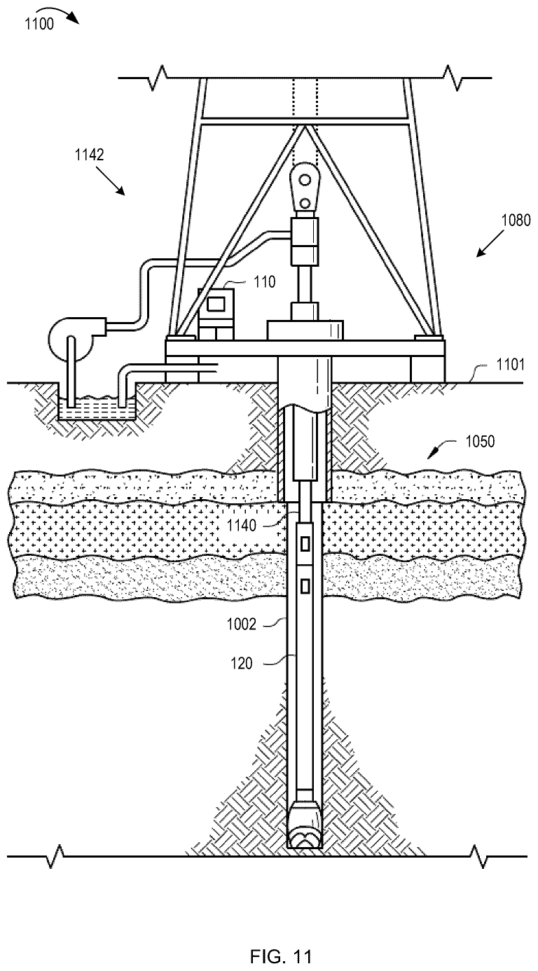

In some implementations, the NMR logging operations can be performed in connection with various types of downhole operations at various stages in the lifetime of a well system. Structural attributes and components of the surface equipment and NMR tool can be adapted for various types of NMR logging operations. For example, NMR logging may be performed during wireline logging operations (e.g., see FIG. 10), during drilling operations (e.g., see FIG. 11), or in other contexts. Accordingly, the surface equipment and the NMR tool may include, or may operate in connection with drilling equipment, wireline logging equipment, or other equipment for other types of operations. As another example, NMR logging may be performed in an offshore or subsea environment. Accordingly, the surface equipment may be arranged on a drill ship or other offshore drilling vessel, and the NMR tool operates in connection with offshore drilling equipment, offshore wireline logging equipment, or other equipment for use with offshore operations.

FIG. 10 shows an example well system 1000 that includes the NMR tool 120 in a wireline logging environment, according to some implementations. The NMR tool 120 may be an example of the NMR tool 120 shown in FIG. 1. In some example wireline logging operations, the surface equipment 1080 may include a platform above the surface equipped with a derrick 1081 that supports a wireline cable 1082 that extends into the wellbore 1002 through the wellhead 1005. Wireline logging operations can be performed, for example, after a drill string is removed from the wellbore 1002, to allow the NMR tool 120 to be lowered by wireline or logging cable into the wellbore 1002.

FIG. 11 shows an example well system 1100 that includes the NMR tool 120 in a drilling environment, according to some implementations. For example, the drilling environment may include performing logging while drilling (LWD) operations or a measurement while drilling (MWD) operations. The NMR tool 120 may be an example of the NMR tool 120 shown in FIG. 1. Drilling is commonly carried out using a string of drill pipes connected together to form a drill string 1140 that is lowered through a rotary table into the wellbore 1002. In some cases, a drilling rig 1142 at the surface 1101 supports the drill string 1140, as the drill string 1140 is operated to drill a wellbore penetrating the subsurface formation 1050. The drill string 1140 may include, for example, a kelly, drill pipe, a bottomhole assembly, and other components. The bottomhole assembly on the drill string may include drill collars, drill bits, the NMR tool 120, and other components, including additional logging tools. The additional logging tools may include MWD tools, LWD tools, and others.

In some implementations, the NMR tool 120 is configured to obtain NMR measurements from the subsurface formation 1050. As shown, for example, in FIG. 10, the NMR tool 120 can be suspended in the wellbore 1002 by a coiled tubing, wireline cable, or another structure that connects the tool to a surface control unit or other components of the surface equipment 1080. In some example implementations, the NMR tool 120 is lowered to the bottom of a region of interest and subsequently pulled upward (e.g., at a substantially constant speed) through the region of interest. As shown, for example, in FIG. 11, the NMR tool 120 can be deployed in the wellbore 1002 on jointed drill pipe, hard wired drill pipe, or other deployment hardware. In some example implementations, the NMR tool 120 collects data (e.g., measurement data) during drilling operations as it moves downward through the region of interest. In some example implementations, the NMR tool 120 collects data while the drill string 1140 is moving, for example, while it is being tripped in or tripped out of the wellbore 1002.

In some implementations, the NMR tool 120 collects data at discrete logging points in the wellbore 1002. For example, the NMR tool 120 can move upward or downward incrementally to each logging point at a series of depths in the wellbore 1002. At each logging point, instruments in the NMR tool 120 perform measurements on the subsurface formations 1050. The measurement data can be communicated to the computer system 110 for storage, processing, and analysis. Such data may be gathered and analyzed during drilling operations (e.g., during LWD/MWD operations), during wireline logging operations, or during other types of activities. The computer system 110 shown in FIGS. 10 and 11 may be configured to receive and analyze the measurement data from the NMR tool 120 to detect properties of the subsurface formation 1050, as previously described above in FIG. 1.

In some implementations, the NMR tool 120 obtains NMR signals by polarizing nuclear spins in the subsurface formation 1050 and pulsing the nuclei with a radio frequency (RF) magnetic field. Various pulse sequences (i.e., series of radio frequency pulses, delays, and other operations) can be used to obtain NMR signals, including the CPMG sequence (in which the spins are first tipped using an excitation (or tipping) pulse followed by a series of refocusing pulses), the Optimized Refocusing Pulse Sequence (ORPS) (in which the refocusing pulses are less than 180°), a saturation recovery pulse sequence, and other pulse sequences. The NMR tool 120 collects measurements relating to spin relaxation time (e.g., T1, T2) distributions as a function of depth or position in the borehole. The NMR tool 120 has a magnet, antenna, and supporting electronics. The permanent magnet in the tool causes the nuclear spins to build up into a cohesive magnetization. The T2 is measured through the decay of excited magnetization while T1 is measured by the buildup of magnetization.

The computer system 110 is configured to process (e.g., invert, transform, etc.) the acquired spin echo signals (or other NMR data) to obtain an NMR signal, such as a relaxation-time distribution (e.g., a distribution of transverse relaxation times T2, or a distribution of longitudinal relaxation times T1, or both). For example, the acquired spin echo signals are integrated using acquisition windows having different durations to generate the different NMR signals. The relaxation-time distribution can be used to determine various physical properties of the formation by solving one or more inverse problems. In some cases, relaxation-time distributions are acquired for multiple logging points and used by the computer system 110 to train a model of the subsurface formation 1050. In some cases, relaxation-time distributions are acquired for multiple logging points and used by the computer system 110 to predict properties of the subsurface formation 1050. The relaxation data may also be referred to as NMR echo train data.

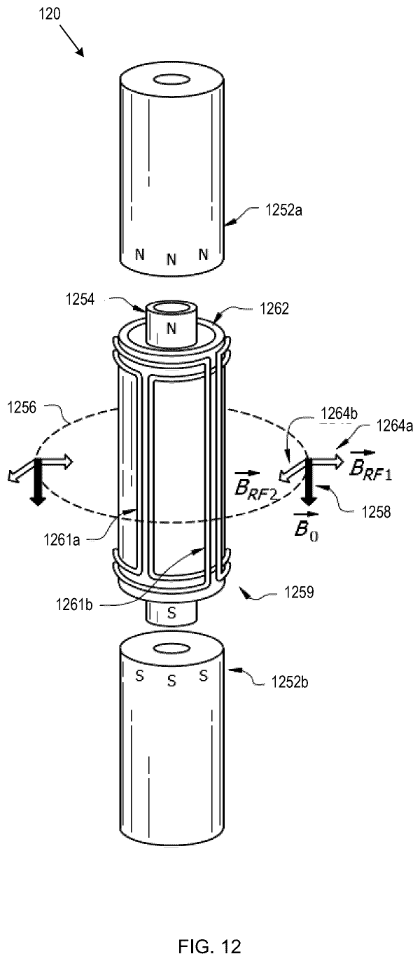

FIG. 12 is a diagram of an example NMR magnet and antenna(s) configuration of an NMR tool 120, according to some implementations. The example NMR tool 120 includes a magnet assembly that generates a static magnetic field to produce polarization, and an antenna assembly that generates a radio frequency (RF) magnetic field to excite nuclei and acquires NMR signals from the surrounding formation. In the non-limiting example shown in FIG. 12, the magnet assembly that includes the end piece magnets 1252a, 1252b and a central magnet 1254 generates the static magnetic field in the volume of investigation 1256. The poles of the central magnet 1254 (e.g., north (N) and south(S)) face the like poles of the proximal end piece magnets 1252a, 1252b. The central magnet 1254 is useful to shape and strengthen the static magnetic field in the volume of investigation 1256. In this example, the volume of investigation 1256 is approximately a cylindrical shell. In the volume of investigation 1256, the direction of the static magnetic field (shown as the solid black arrow 1258) is parallel to the longitudinal axis of the wellbore. In some examples, a magnet configuration with a bigger central magnet can be used to create a double pole strength and therefore increase the strength of the magnetic field (e.g., up to 100-150 Gauss or higher in some instances).

In the non-limiting example shown in FIG. 12, the antenna assembly 1259 includes two mutually orthogonal transversal dipole antennas 1261a, 1261b. In some instances, the NMR tool 120 can be implemented with a single transversal-dipole antenna. For example, one of the orthogonal transversal-dipole antennas 1261a, 1261b may be omitted from the antenna assembly 1259. The example orthogonal transversal-dipole antenna 1261a, 1261b shown in FIG. 12 are placed on an outer surface of a soft magnetic core 1262, which is useful for RF magnetic flux concentration. The antenna assembly 1259 generates two orthogonal RF magnetic fields 1264a (e.g., produced by the antenna 1261a) and 1264b (e.g., produced by the antenna 1261b). The two RF magnetic fields 1264 a, 1264 b have a phase shift of 90°. Accordingly, the RF magnetic fields 1264a, 1264b generate a circular polarized RF magnetic field to excite NMR in the surrounding formation more efficiently. It is also possible to only transmit with one antenna, even if a second antenna is included in the assembly. For example, the second antenna could be used only to receive NMR signals in this configuration. The same two orthogonal transversal-dipole antennas 1261a, 1261b are used to receive NMR signals from the surrounding formation. The received NMR signals are from induced currents from the NMR magnetization. The signals in the orthogonal transversal-dipole antennas 1261a, 1261b, may then be processed (e.g., by the computer system 110 of FIGS. 1 and 9-11) together in order to increase a signal-to-noise ratio (SNR) of the acquired NMR data.

In some implementations, the antenna assembly 1259 additionally or alternatively includes an integrated coil set that performs the operations of the two orthogonal transversal-dipole antennas 1261a, 1261b. For example, the integrated coil may be useful (e.g., instead of the two orthogonal transversal-dipole antennas 1261a, 1261b) to produce circular polarization and perform quadrature coil detection. Examples of integrated coil sets that can be adapted to perform such operations include multi-coil or complex single-coil arrangements, such as, for example, birdcage coils used for high-field magnetic resonance imaging (MRI). It is noted that the specific geometry and/or configuration of the NMR tool 120 is not necessarily limited to that shown in FIG. 12, and in other implementations, the NMR tool 120 may have different geometry and/or configurations.

Although some example well systems are described in FIGS. 1-12, it is noted, however, that the ringing noise measurement techniques and operations described in FIGS. 1-12 can be used in any type of well system in the oil and gas industry.

As will be appreciated, aspects of the disclosure may be embodied as a system, method or program code/instructions stored in one or more machine-readable media. Accordingly, aspects may take the form of hardware, software (including firmware, resident software, micro-code, etc.), or a combination of software and hardware aspects that may all generally be referred to herein as a “circuit,” “module” or “system.” The functionality presented as individual modules/units in the example illustrations can be organized differently in accordance with any one of platform (operating system and/or hardware), application ecosystem, interfaces, programmer preferences, programming language, administrator preferences, etc.

Any combination of one or more machine-readable medium(s) may be utilized. The machine-readable medium may be a machine-readable signal medium or a machine-readable storage medium. A machine-readable storage medium may be, for example, but not limited to, a system, apparatus, or device, that employs any one of or combination of electronic, magnetic, optical, electromagnetic, infrared, or semiconductor technology to store program code. More specific examples (a non-exhaustive list) of the machine-readable storage medium would include the following: a portable computer diskette, a hard disk, a random-access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a machine-readable storage medium may be any tangible medium that can contain, or store a program for use by or in connection with an instruction execution system, apparatus, or device. A machine-readable storage medium is not a machine-readable signal medium.

A machine-readable signal medium may include a propagated data signal with machine-readable program code embodied therein, for example, in baseband or as part of a carrier wave. Such a propagated signal may take any of a variety of forms, including, but not limited to, electro-magnetic, optical, or any suitable combination thereof. A machine-readable signal medium may be any machine-readable medium that is not a machine-readable storage medium and that can communicate, propagate, or transport a program for use by or in connection with an instruction execution system, apparatus, or device.

Program code embodied on a machine-readable medium may be transmitted using any appropriate medium, including but not limited to wireless, wireline, optical fiber cable, RF, etc., or any suitable combination of the foregoing.

Computer program code for carrying out operations for aspects of the disclosure may be written in any combination of one or more programming languages, including an object oriented programming language such as the Java® programming language, C++ or the like; a dynamic programming language such as Python; a scripting language such as Perl programming language or PowerShell script language; and conventional procedural programming languages, such as the “C” programming language or similar programming languages. The program code may execute entirely on a stand-alone machine, may execute in a distributed manner across multiple machines, and may execute on one machine while providing results and or accepting input on another machine.

The program code/instructions may also be stored in a machine-readable medium that can direct a machine to function in a particular manner, such that the instructions stored in the machine-readable medium produce an article of manufacture including instructions which implement the function/act specified in the flowchart and/or block diagram block or blocks.

None of the implementations described herein may be performed exclusively in the human mind nor exclusively using pencil and paper. None of the implementations described herein may be performed without computerized components such as those described herein. Some implementations may perform additional operations, fewer operations, operations in parallel or in a different order, and some operations differently.

While the aspects of the disclosure are described with reference to various implementations and exploitations, it will be understood that these aspects are illustrative and that the scope of the claims is not limited to them. In general, techniques for performing NMR measurements and measuring the ringing noise as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations, and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

As used herein, the term “or” is inclusive unless otherwise explicitly noted. Thus, the phrase “at least one of A, B, or C” is satisfied by any element from the set {A, B, C} or any combination thereof, including multiples of any element.

Furthermore, unless otherwise specified, use of the terms “up,” “upper,” “upward,” “uphole,” “upstream,” or other like terms shall be construed as generally away from the bottom, terminal end of a well; likewise, use of the terms “down,” “lower,” “downward,” “downhole,” or other like terms shall be construed as generally toward the bottom, terminal end of the well, regardless of the wellbore orientation. Use of any one or more of the foregoing terms shall not be construed as denoting positions along a perfectly vertical axis. In some instances, a part near the end of the well can be horizontal or even slightly directed upwards. Unless otherwise specified, use of the term “subterranean formation” shall be construed as encompassing both areas below exposed earth and areas below earth covered by water such as ocean or fresh water.

### EXAMPLE EMBODIMENTS

Example Embodiments can include the following:

Embodiment #1: A method for obtaining nuclear magnetic resonance (NMR) measurements of a subsurface formation in a well system, comprising: generating one or more NMR pulses downhole using an NMR tool of the well system; determining whether an amplitude of an NMR echo signal is less than or equal to a threshold level or the NMR echo signal is not present; and measuring ringing noise associated with the one or more NMR pulses when the amplitude of the NMR echo signal is less than or equal to the threshold level or the NMR echo signal is not present.

Embodiment #2: The method of Embodiment #1, wherein the one or more NMR pulses include an excitation pulse and a plurality of refocusing pulses of an NMR echo train, further comprising: detecting the NMR echo signal of the NMR echo train; determining when the amplitude of the NMR echo signal is less than or equal to the threshold level; and measuring the ringing noise associated with the NMR echo train when the amplitude of the NMR echo signal is less than or equal to the threshold level.

Embodiment #3: The method of Embodiment #2, wherein: the threshold level is a noise level; the threshold level is a signal level when the amplitude of the NMR echo signal is less than an amplitude of the ringing noise; or the threshold level is a signal level representing the NMR echo signal decaying towards a zero amplitude according to a decay curve.

Embodiment #4: The method of Embodiment #1, wherein the one or more NMR pulses include a nullification pulse, an excitation pulse and a plurality of refocusing pulses of an NMR echo train, further comprising: detecting the NMR echo signal of the NMR echo train, the NMR echo train including the nullification pulse; determining when the amplitude of the NMR echo signal is less than or equal to the threshold level; and measuring the ringing noise associated with the NMR echo train when the amplitude of the NMR echo signal is less than or equal to the threshold level.

Embodiment #5: The method of Embodiment #4, wherein: the threshold level is a noise level; the threshold level is a signal level when the amplitude of the NMR echo signal is less than an amplitude of the ringing noise; or the threshold level is a signal level representing the NMR echo signal decaying towards a zero amplitude according to a decay curve.

Embodiment #6: The method of Embodiment #5, wherein the NMR echo train having the nullification pulse results in a shortened NMR echo train by reducing a decay time of the decay curve associated with the NMR echo signal.

Embodiment #7: The method of Embodiment #1, wherein the one or more NMR pulses include a nullification pulse and a plurality of refocusing pulses, further comprising: determining that the NMR echo signal is not present; and measuring the ringing noise associated with one or more of the plurality of refocusing pulses after the nullification pulse in response to determining the NMR echo signal is not present.

Embodiment #8: The method of Embodiment #1, wherein the one or more NMR pulses include a plurality of refocusing pulses, further comprising: determining that the NMR echo signal is not present; and measuring the ringing noise associated with one or more of the plurality of refocusing pulses in response to determining the NMR echo signal is not present.

Embodiment #9: The method of Embodiment #1, further comprising: performing a plurality of measurements of the ringing noise; and averaging the plurality of measurements to obtain an average ringing noise measurement.

Embodiment #10: The method of Embodiment #1, further comprising: cancelling the ringing noise from the NMR measurements; and determining properties of the subsurface formation from the NMR measurements after cancelling the ringing noise.

Embodiment #11: A well system for obtaining nuclear magnetic resonance (NMR) measurements of a subsurface formation, the well system comprising: an NMR tool configured to generate one or more NMR pulses downhole; one or more processors; and a computer-readable storage medium having instructions stored thereon that are executable by the one or more processors to cause the well system to: determine whether an amplitude of an NMR echo signal is less than or equal to a threshold level or the NMR echo signal is not present; and measure ringing noise associated with the one or more NMR pulses when the amplitude of the NMR echo signal is less than or equal to the threshold level or the NMR echo signal is not present.

Embodiment #12: The well system of claim Embodiment #11, wherein the one or more NMR pulses include an excitation pulse and a plurality of refocusing pulses of an NMR echo train, further comprising instructions that cause the well system to: detect the NMR echo signal of the NMR echo train; determine when the amplitude of the NMR echo signal is less than or equal to the threshold level; and measure the ringing noise associated with the NMR echo train when the amplitude of the NMR echo signal is less than or equal to the threshold level.

Embodiment #13: The well system of Embodiment #11, wherein the one or more NMR pulses include a nullification pulse, an excitation pulse and a plurality of refocusing pulses of an NMR echo train, further comprising instructions that cause the well system to: detect the NMR echo signal of the NMR echo train, the NMR echo train including the nullification pulse; determine when the amplitude of the NMR echo signal is less than or equal to the threshold level; and measure the ringing noise associated with the NMR echo train when the amplitude of the NMR echo signal is less than or equal to the threshold level.

Embodiment #14: The well system of Embodiment #11, wherein the one or more NMR pulses include a nullification pulse and a plurality of refocusing pulses, further comprising instructions that cause the well system to: determine that the NMR echo signal is not present; and measure the ringing noise associated with one or more of the plurality of refocusing pulses after the nullification pulse in response to determining the NMR echo signal is not present.

Embodiment #15: The well system of Embodiment #11, wherein the one or more NMR pulses include a plurality of refocusing pulses, further comprising instructions that cause the well system to: determine that the NMR echo signal is not present; and measure the ringing noise associated with one or more of the plurality of refocusing pulses in response to determining the NMR echo signal is not present.

Embodiment #16: A non-transitory computer-readable storage medium having instructions stored thereon that are executable by one or more processors of a well system, the well system for obtaining nuclear magnetic resonance (NMR) measurements of a subsurface formation, the instructions comprising: instructions for generating one or more NMR pulses downhole using an NMR tool of the well system; instructions for determining whether an amplitude of an NMR echo signal is less than or equal to a threshold level or the NMR echo signal is not present; and instructions for measuring ringing noise associated with the one or more NMR pulses when the amplitude of the NMR echo signal is less than or equal to the threshold level or the NMR echo signal is not present.

Embodiment #17: The non-transitory computer-readable storage medium of Embodiment #16, wherein the one or more NMR pulses include an excitation pulse and a plurality of refocusing pulses of an NMR echo train, further comprising: instructions for detecting the NMR echo signal of the NMR echo train; instructions for determining when the amplitude of the NMR echo signal is less than or equal to the threshold level; and instructions for measuring the ringing noise associated with the NMR echo train when the amplitude of the NMR echo signal is less than or equal to the threshold level.

Embodiment #18: The non-transitory computer-readable storage medium of Embodiment #16, wherein the one or more NMR pulses include a nullification pulse, an excitation pulse and a plurality of refocusing pulses of an NMR echo train, further comprising: instructions for detecting the NMR echo signal of the NMR echo train, the NMR echo train including the nullification pulse; instructions for determining when the amplitude of the NMR echo signal is less than or equal to the threshold level; and instructions for measuring the ringing noise associated with the NMR echo train when the amplitude of the NMR echo signal is less than or equal to the threshold level.

Embodiment #19: The non-transitory computer-readable storage medium of Embodiment #16, wherein the one or more NMR pulses include a nullification pulse and a plurality of refocusing pulses, further comprising: instructions for determining that the NMR echo signal is not present; and instructions for measuring the ringing noise associated with one or more of the plurality of refocusing pulses after the nullification pulse in response to determining the NMR echo signal is not present.

Embodiment #20: The non-transitory computer-readable storage medium of Embodiment #16, wherein the one or more NMR pulses include a plurality of refocusing pulses, further comprising: instructions for determining that the NMR echo signal is not present; and instructions for measuring the ringing noise associated with one or more of the plurality of refocusing pulses in response to determining the NMR echo signal is not present.

What is claimed is:

1. A method for obtaining nuclear magnetic resonance (NMR) measurements of a subsurface formation in a well system, comprising:
generating one or more NMR pulses downhole using an NMR tool of the well system;
determining whether an amplitude of an NMR echo signal is less than or equal to a threshold level or the NMR echo signal is not present; and
measuring ringing noise associated with the one or more NMR pulses when the amplitude of the NMR echo signal is less than or equal to the threshold level or the NMR echo signal is not present.

2. The method of claim 1, wherein the one or more NMR pulses include an excitation pulse and a plurality of refocusing pulses of an NMR echo train, further comprising:
detecting the NMR echo signal of the NMR echo train;
determining when the amplitude of the NMR echo signal is less than or equal to the threshold level; and
measuring the ringing noise associated with the NMR echo train when the amplitude of the NMR echo signal is less than or equal to the threshold level.

3. The method of claim 2, wherein:
the threshold level is a noise level;
the threshold level is a signal level when the amplitude of the NMR echo signal is less than an amplitude of the ringing noise; or
the threshold level is a signal level representing the NMR echo signal decaying towards a zero amplitude according to a decay curve.

4. The method of claim 1, wherein the one or more NMR pulses include a nullification pulse, an excitation pulse and a plurality of refocusing pulses of an NMR echo train, further comprising:
detecting the NMR echo signal of the NMR echo train, the NMR echo train including the nullification pulse;
determining when the amplitude of the NMR echo signal is less than or equal to the threshold level; and
measuring the ringing noise associated with the NMR echo train when the amplitude of the NMR echo signal is less than or equal to the threshold level.

5. The method of claim 4, wherein:
the threshold level is a noise level;
the threshold level is a signal level when the amplitude of the NMR echo signal is less than an amplitude of the ringing noise; or
the threshold level is a signal level representing the NMR echo signal decaying towards a zero amplitude according to a decay curve.

6. The method of claim 5, wherein the NMR echo train having the nullification pulse results in a shortened NMR echo train by reducing a decay time of the decay curve associated with the NMR echo signal.

7. The method of claim 1, wherein the one or more NMR pulses include a nullification pulse and a plurality of refocusing pulses, further comprising:
determining that the NMR echo signal is not present; and
measuring the ringing noise associated with one or more of the plurality of refocusing pulses after the nullification pulse in response to determining the NMR echo signal is not present.

8. The method of claim 1, wherein the one or more NMR pulses include a plurality of refocusing pulses, further comprising:
determining that the NMR echo signal is not present; and
measuring the ringing noise associated with one or more of the plurality of refocusing pulses in response to determining the NMR echo signal is not present.

9. The method of claim 1, further comprising:
performing a plurality of measurements of the ringing noise; and
averaging the plurality of measurements to obtain an average ringing noise measurement.

10. The method of claim 1, further comprising:
cancelling the ringing noise from the NMR measurements; and
determining properties of the subsurface formation from the NMR measurements after cancelling the ringing noise.

11. A well system for obtaining nuclear magnetic resonance (NMR) measurements of a subsurface formation, the well system comprising:
an NMR tool configured to generate one or more NMR pulses downhole;
one or more processors; and
a computer-readable storage medium having instructions stored thereon that are executable by the one or more processors to cause the well system to:
determine whether an amplitude of an NMR echo signal is less than or equal to a threshold level or the NMR echo signal is not present; and
measure ringing noise associated with the one or more NMR pulses when the amplitude of the NMR echo signal is less than or equal to the threshold level or the NMR echo signal is not present.

12. The well system of claim 11, wherein the one or more NMR pulses include an excitation pulse and a plurality of refocusing pulses of an NMR echo train, further comprising instructions that cause the well system to:
detect the NMR echo signal of the NMR echo train;
determine when the amplitude of the NMR echo signal is less than or equal to the threshold level; and
measure the ringing noise associated with the NMR echo train when the amplitude of the NMR echo signal is less than or equal to the threshold level.

13. The well system of claim 11, wherein the one or more NMR pulses include a nullification pulse, an excitation pulse and a plurality of refocusing pulses of an NMR echo train, further comprising instructions that cause the well system to:
detect the NMR echo signal of the NMR echo train, the NMR echo train including the nullification pulse;
determine when the amplitude of the NMR echo signal is less than or equal to the threshold level; and
measure the ringing noise associated with the NMR echo train when the amplitude of the NMR echo signal is less than or equal to the threshold level.

14. The well system of claim 11, wherein the one or more NMR pulses include a nullification pulse and a plurality of refocusing pulses, further comprising instructions that cause the well system to:
determine that the NMR echo signal is not present; and
measure the ringing noise associated with one or more of the plurality of refocusing pulses after the nullification pulse in response to determining the NMR echo signal is not present.

15. The well system of claim 11, wherein the one or more NMR pulses include a plurality of refocusing pulses, further comprising instructions that cause the well system to:
determine that the NMR echo signal is not present; and
measure the ringing noise associated with one or more of the plurality of refocusing pulses in response to determining the NMR echo signal is not present.

16. A non-transitory computer-readable storage medium having instructions stored thereon that are executable by one or more processors of a well system, the well system for obtaining nuclear magnetic resonance (NMR) measurements of a subsurface formation, the instructions comprising:
instructions for generating one or more NMR pulses downhole using an NMR tool of the well system;
instructions for determining whether an amplitude of an NMR echo signal is less than or equal to a threshold level or the NMR echo signal is not present; and
instructions for measuring ringing noise associated with the one or more NMR pulses when the amplitude of the NMR echo signal is less than or equal to the threshold level or the NMR echo signal is not present.

17. The non-transitory computer-readable storage medium of claim 16, wherein the one or more NMR pulses include an excitation pulse and a plurality of refocusing pulses of an NMR echo train, further comprising:
instructions for detecting the NMR echo signal of the NMR echo train;
instructions for determining when the amplitude of the NMR echo signal is less than or equal to the threshold level; and
instructions for measuring the ringing noise associated with the NMR echo train when the amplitude of the NMR echo signal is less than or equal to the threshold level.

18. The non-transitory computer-readable storage medium of claim 16, wherein the one or more NMR pulses include a nullification pulse, an excitation pulse and a plurality of refocusing pulses of an NMR echo train, further comprising:
instructions for detecting the NMR echo signal of the NMR echo train, the NMR echo train including the nullification pulse;
instructions for determining when the amplitude of the NMR echo signal is less than or equal to the threshold level; and
instructions for measuring the ringing noise associated with the NMR echo train when the amplitude of the NMR echo signal is less than or equal to the threshold level.

19. The non-transitory computer-readable storage medium of claim 16, wherein the one or more NMR pulses include a nullification pulse and a plurality of refocusing pulses, further comprising:
instructions for determining that the NMR echo signal is not present; and
instructions for measuring the ringing noise associated with one or more of the plurality of refocusing pulses after the nullification pulse in response to determining the NMR echo signal is not present.

20. The non-transitory computer-readable storage medium of claim 16, wherein the one or more NMR pulses include a plurality of refocusing pulses, further comprising:
instructions for determining that the NMR echo signal is not present; and
instructions for measuring the ringing noise associated with one or more of the plurality of refocusing pulses in response to determining the NMR echo signal is not present.
